(19) United States
(12) Patent Application Publication
(10) Pub. No.: US 2014/0193743 A1
(43) Pub. Date: Jul. 10, 2014

(54) METHOD FOR THE DENSIFICATION OF CERAMIC LAYERS, ESPECIALLY CERAMIC LAYERS WITHIN SOLID OXIDE CELL (SOC) TECHNOLOGY, AND PRODUCTS OBTAINED BY THE METHOD

(71) Applicant: Vincenzo Esposito, Malmo (SE)

(72) Inventor: Vincenzo Esposito, Malmo (SE)

(73) Assignee: DANMARKS TEKNISKE UNIVERSITET, Lybgby (DK)

(21) Appl. No.: 14/233,721

(22) PCT Filed: Jul. 20, 2012
(86) PCT No.: PCT/DK2012/050275

§ 371 Date: Mar. 20, 2014

(30) Foreign Application Priority Data
Jul. 22, 2011 (DK) PA 2011 00562

(51) Int. Cl. C04B 41/45; H01L 41/187; C04B 41/00; H01M 8/02; C25B 9/06

(52) U.S. Cl. CPC C04B 41/4582; H01M 8/0245; C25B 9/06; C04B 41/0072; H01L 41/187
USPC 429/495; 428/312.8; 204/242; 427/58; 427/123; 216/37; 310/311

(57) ABSTRACT

A ceramic layer, especially for use in solid oxide cell (SOC) technology, is densified in a method comprising (a) providing a multilayer system by depositing the porous ceramic layer, which is to be densified, onto the selected system of ceramic layers on a support, (b) pre-sintering the resulting multilayer system at a temperature T₁ to consolidate a sintered, but porous layer, (c) impregnating a solution or suspension of one or more sintering aids directly into the layer to be densified, (d) evaporating the solution or suspension of step (c) to obtain a homogeneous dispersion of the sintering aid(s) in the porous layer surface and (e) performing a thermal treatment at a temperature T₂, where T₂>T₁, to obtain densification of and grain growth in the porous layer formed in step (b). The method makes it possible to obtain dense ceramic layers at temperatures, which are compatible with the other materials present in a ceramic multilayer system.

### FIELD OF INVENTION

The present invention relates to a method for the densification of ceramic layers, especially ceramic layers within solid oxide cell (SOC) technology, by an in-situ solid state reaction. The expression “in-situ solid state reaction” in this instance refers to a reactive sintering procedure where the material to be densified, i.e. a ceramic layer, is solid, whereas the sintering aid(s) involved in the process can be either liquid or solid depending on the temperatures and properties of the specific sintering aid. The invention further relates to products obtained by the method.

### BACKGROUND OF THE INVENTION

Solid oxide cells (SOCs) generally include cells designed for different applications, such as solid oxide fuel cells (SOFCs) or solid oxide electrolysis cells (SOECs). Due to the common basic structure thereof, the same cell may be used in SOFC applications as well as in SOEC applications. Since in SOFCs fuel is fed into the cell and converted to power, while in SOECs power is applied to produce fuel, these cells are referred to as being “reversible”.

Solid oxide fuel cells (SOFCs) are well known in the art and are available in various designs. Typical configurations include an electrolyte layer sandwiched in between two electrodes, i.e. an anode (fuel electrode) and a cathode (air electrode). The function of an anode in the SOFC is to react electrochemically with the fuel, which may be hydrogen and hydrocarbons, while the cathode reacts with oxygen to produce electric current. The electrodes are usually porous oxide layers of electronic or mixed ionic/electronic materials and/or composites. The electrolyte is typically a dense oxide ionic conductive material. Between the electrolyte and an electrode, e.g. the cathode, a dense barrier layer may be inserted to prevent chemical interaction between the cathode and the electrolyte materials.

The most common manufacturing processes for SOFCs suggested in the prior art comprise the manufacture of single cells. Generally, a support is provided by conventional casting techniques, and on said support an anode layer is formed in the “green”, i.e. non-sintered state, followed by the application of an electrolyte layer and/or a barrier layer in their respective green states, for example by multi casting techniques. The so-formed half cell is dried and afterwards sintered at temperatures of up to 1600° C., in some cases in a reducing atmosphere. The second electrode layer, i.e. the cathode, is usually deposited on the sintered half cell by different deposition techniques, such as screen printing, spray-coating etc., and sintered by a further sintering treatment. In some cases, before the deposition and sintering of the cathode take place, also the barrier layer is deposited and sintered onto the sintered half cell in a separate processing step. In the processing, the selection of the sintering temperatures is aimed at obtaining an optimized configuration of the multilayer system, where the electrolyte and barrier layers are dense while the support and electrode layers are porous.

However, the sintering step disadvantageously leads to a number of problems. For the green body, the planar shape of the layers tends to undergo bending during sintering, because the different layers have a different shrinkage and thermal expansion coefficient which causes contact problems if said cell subsequently is to be used in a cell stack. Cells being deformed cannot be used and are therefore discarded, making mass production very cost extensive and also material extensive and so far unpractical for today's industrial requirements. Moreover, use of high temperatures can lead to excessive densification of the electrodes and detrimental solid state reactions between the components at the interface. On the other hand, low sintering temperatures do not allow the desired air tightness by full densification of electrolyte and also the resulting barrier layer can be porous. Thereby, the ohmic resistance of the cell may increase, and the barrier properties towards the chemical reactivity of the layers may get lost. In addition, delamination as well as nucleation of defects may occur in the interface between the layers, whereby the mechanical strength of the ceramic multilayer system is reduced.

Sintering aids are widely used to densify materials at lower temperatures than otherwise possible, usually to densify at the limiting sintering temperature used in the process. However, in addition to the temperature-lowering effect, it is also necessary to focus on the effect that a given sintering aid has on the electrochemical properties of the sintered body, when the intended use thereof is within solid oxide cell technology. Thus, the selection of sintering aids also has to be made with a view to the final function of the layers without impairing the electrochemical properties of the material to be sintered. For example, SiO₂ is an excellent sintering aid for many ceramics but, even in small quantities, it is detrimental to the ultimate electrical properties of electroceramics. Therefore, there is an ongoing research to find improved sintering procedures and sintering aids leading to better material properties.

A number of prior art publications describe sintering of multilayer structures in one or more steps for various intended uses. Thus, US 2003/0021900 A1 concerns a method for making dense crack-free thin ceramic films, the method comprising depositing a layer of a ceramic material on a porous or dense substrate. The deposited layer is compacted and then the resultant laminate is sintered to achieve a higher density than would have been possible without the pre-sintering compaction step. U.S. Pat. No. 6,251,473 B1 describes the preparation of ceramic thin films by spray coating and sintering, and WO 2006/074932 A1 concerns a method for shrinkage and porosity control during sintering of multilayer structures. Methods of processing ceramic layers and related articles, especially for use in fuel cells, are described in US 2009/0075146 A1, and US 2010/0092842 A1 describes densified ceramic materials and related methods, also especially for use in fuel cells. WO 2010/0055111 describes a partially oxidized substrate obtained by subjecting a substrate made of a porous metal or metal alloy comprising particles of at least one metal or metal alloy bound together by sintering, said substrate comprising a first main surface and a second main surface, and said substrate having a porosity gradient from the first main surface to the second main surface, with partial oxidation by an oxidizing gas such as oxygen and/or air. The publication also describes SOFCs having a support metal comprising this substrate. CN 1438722 A concerns a method for making a tube-like high temperature SOFC of ceramic/metal support type. The anode layer, the electrolyte layer and the cathode layer of the fuel cell are all prepared through spray coating formation. In order to increase air tightness of the electrolyte layer, a densification treatment is carried out for the electrolyte layer after spray coating formation. The method allegedly simplifies the technique for producing the fuel cell, thereby lowering the cost. In JP 10017377 A an electrolyte plate and a ceramic reinforcing material are described along with production methods therefore. U.S. Pat. No. 6,228,520 B1 concerns a co-sinterable ceramic interconnect for solid state electrochemical cells, including SOFCs, and U.S. Pat. No. 5,162,167 B1 describes an apparatus and a method, including a two-step densifying process, for fabricating a monolithic SOFC. In U.S. Pat. No. 6,436,565 a fuel electrode-supported tubular SOFC is described along with the manufacturing process thereof, according to which YSZ powder containing 30-50 vol % Ni is mixed with carbon powder to give a fuel electrolyte slurry which is pre-sintered, coated onto a fuel electrode tube, and then the coated tube is sintered. Then an air electrode slurry of (La,Sr)MnO₃ powder is coated onto the electrolyte-coated tube and sintered. Finally, US 2010/0230871 discloses a method of sintering a ceramic material, said method comprising several sintering procedures at different temperatures without intermediate impregnation of sintering aids. The overall method increases the density of the ceramic material. It is used for electrolyte layers of solid oxide fuel cells.

Thus, sintering technology is widely used to densify ceramic materials, often assisted by sintering aids. When sintering aids are used, they are usually mixed with the starting ceramic powders or used as a coating on said powders. However, such techniques can be ineffective as regards the formation of a dense thin ceramic layer because the stress generated during the processing of the multilayer system can induce phenomena of creep or constrained sintering. Ceramic powders which are simply mixed with or covered by a sintering aid can thus, at high temperatures, be subject to severe viscous flow among the particles and at the grain boundaries, leading to poorly sintered layers with formation of porosity or other defects during processes at high temperatures.

### SUMMARY OF THE INVENTION

These problems can be overcome by the method for the densification of ceramic layers according to the invention, said method comprising an in-situ solid state reaction. According to the invention pre-sintered porous ceramic layers, which are supported on other ceramic layers or supports, are densified by a novel methodology which can be included or integrated as an additional processing step in the procedure for the preparation of a multilayer ceramic system. The methodology underlying the present invention is aimed at the densification of top-layers which present limitations in terms of densification because of constrained sintering conditions, high sintering temperatures compared to the other layers, etc. The purpose of the present invention is to obtain a dense ceramic layer at temperatures, which are compatible with the other materials present in a ceramic multilayer system.

Therefore, in a first aspect the present invention concerns a method for the densification of ceramic layers, especially ceramic layers within solid oxide cell (SOC) technology, by an in-situ solid state reaction (SSR reaction), said method comprising the following steps:
(a) providing a multilayer system by depositing the porous ceramic layer, which is to be densified, onto the selected system of ceramic layers on a support,
(b) pre-sintering the resulting multilayer system at a temperature T₁ to promote the formation of a sintered porous microstructure in the layer to be densified, thereby consolidating a sintered, but porous layer,
(c) impregnating a solution or suspension of one or more sintering aids directly into the layer to be densified,
(d) evaporating the solution or suspension of step (c) to obtain a homogeneous dispersion of the sintering aid(s) in the porous layer surface and
(e) performing a thermal treatment at a temperature T₂, where T₂>T₁, to obtain densification of and grain growth in the porous layer.

The deposition of the porous ceramic layer in step (a) can be done by any deposition method known in the art, e.g. by casting, multi casting and lamination at the green stage, by screen printing, by spraying techniques, by PVD (physical vapour deposition) or by CVD (chemical vapour deposition).

The pre-sintering temperature T₁ in step (b) is chosen so as to obtain the mechanical and chemical properties required and to achieve the early particles necking with a certain degree of open porosity. Use of a small amount of sintering aid in the starting powders could also be considered for step (b) if the particle necking is too limited at the processing temperatures. The sintering aids can be selected among melting salts, melting or highly diffusive oxides and other transition-metal based compounds.

The thermal treatment in step (e) is performed in order to:
dry and decompose the component of the sintering aid(s) solution, which impregnate into the surface porosity of the ceramic layer,
liquefy the melting salts and/or oxidize the sintering aid(s) into the active metal oxide form,
melt or activate the diffusivity of the sintering aid(s) simultaneously with the porous layer material and
evaporating the sintering aid(s) if necessary and when possible.

The temperature ranges and holding times at the different temperatures depend on the specific physical properties of the sintering aid(s) and on the presence of other additives such as dispersants, surfactants etc. The use of a thermal treatment at a temperature T₂>T₁ is crucial to reactivate the sintering and grain growth mechanisms in the porous layer after having been pre-sintered at a temperature T₁. The diffusion and penetration of the sintering aid(s) through the layer will depend on the initial porosity of the layer and on the time and temperatures used in the process. An excess of one or more sintering aids is usually associated to the present method.

Traces of sintering aids segregated at a high temperature (i.e. T₂) can usually be detected in the microstructure crystallized at the layer surface and/or trapped in the primary porosity and/or in the substrate/layer interface. However, such traces can be partially or completely removed from the layer surface by chemical etching and by additional treatments at the evaporation temperature(s) of the sintering aid(s). A selected chemical etching to remove the sintering aid(s) can also be used, if necessary and/or applicable, to clean the layer surface as a final step in the process.

In the preparation of a multilayer system to be used in the process of the invention the densification of a given top layer can be followed by the deposition and densification of further porous layers. Thus, the method can be applied to obtain a sequel of densified ceramic layers starting from a primary pre-sintered support.

By the in-situ solid state reaction method according to the invention the layer is first sintered and consolidated, and particles are connected in the absence of, or with limited use of, sintering aids in the pre-sintering step (b). This allows for an effective action of the selected sintering aid over the sintering mechanism and the possibility of an optimized tailoring of the final microstructure in the ceramic layer, and contamination of the grain boundary is reduced.

The present invention has mainly been developed for the densification of barrier layers of doped cerium oxide (e.g. gadolinium-doped cerium oxide (CGO)) within solid oxide fuel cell (SOFC) technology, but it may be used for the densification of ceramic multilayer systems in general. In fact the technology is compatible with the processing of many multilayer ceramic systems where the layer, which is to be densified, can be impregnated by using sintering aids in solution or suspension.

Typical sintering aids to be impregnated into the layer of doped cerium oxide or the like would be Co, Fe, Cr, Mn, Ni, Zn, Cu, Bi, Li, K, Ca or Ba salts and/or oxides and their mixtures. These sintering aids present a high diffusivity in the temperature range about 600-1400° C. and electrical conductivity/catalytic properties under the operative conditions of SOFCs.

A much preferred sintering aid to be used in sintering of gadolinium-doped cerium oxide (CGO) is cobalt, either as oxides or as salts. Cobalt oxide is highly diffusive at high temperature, but scarcely soluble in CGO, and it is an electric conductor which, in low concentrations, does not impair the electrical properties of the CGO. Salts, e.g. cobalt nitrate, liquefy, decompose and oxidize into cobalt oxide during the firing process.

In some other embodiments other sintering aids having high diffusion coefficient and limited solubility in CGO may be used.

With the method according to the invention any porosity due to the constrained sintering of a thin layer on a sintered and/or dense support is eliminated. This is achieved by the aimed action of the sintering aid with a designed thermal treatment.

Furthermore, with the method according to the invention it has become possible to refrain from the use of sintering aids added on a process level prior to the first (and only) sintering and/or the use of chemical or physical techniques for the formation of dense layers for materials presenting poor sintering behaviour when shaped as films. The method according to the invention can also be regarded as supplemental to various layer shaping techniques, such as tape casting, or other deposition techniques, such as screen printing or spraying techniques, together with conventional sintering at high temperatures.

The method of the invention presents a number of advantages over the prior art methods. First of all it is possible to obtain densification of ceramic layers under constrained sintering conditions. It is also possible to carry out densifications at reduced sintering temperatures (T₂) depending on the sintering aid(s) used in the method, compared to a conventional sintering procedure with no sintering aid(s) present. Furthermore, an optimized dense ceramic layer may be obtained by careful tailoring of the microstructure of the ceramic layer. In addition, metal dopants may be added at grain boundaries if this turns out to be beneficial.

A further advantage of the method is that at the final step the porous layer reduces its thickness by a percentage corresponding to the volume of the original porosity in the pre-sintered layer, typically 20-40%.

In a second aspect of the invention, the object and further objects of the present invention may be achieved through a multilayer system with a densified ceramic layer produced by a method according to the first aspect of the invention, for use within piezoelectric technology.

In a third aspect of the invention, the object and further objects of the present invention may be achieved through a multilayer system, comprising: a selected system of ceramic layers on a support and at least one densified porous ceramic layer, located on top of the selected system of ceramic layers.

In some embodiments according to the third aspect of the invention the at least one densified porous ceramic layer has a structure where a grain size (g) and thickness (t) of the at least one densified porous ceramic layer stand in relation to one another as given by equation

g/t>0.1

In the prior art to provide layer thicknesses, e.g. of 5 micrometer, grain sizes of around 100 nm may be used, leading to limited growth of the grains, e.g. up to 200 nm. This is not the case of the method of the invention where larger grain growth is possible for layers of comparable thicknesses. For example, growths up to 500 nm in grain size are possible in layers having 1 micrometers of thickness.

Thus, with the method of the invention it is possible to obtain multilayer systems having densified porous ceramic layer with a ratio, grain size vs thickness, larger than 0.1.

In some other embodiments according to the third aspect of the invention the at least one densified porous ceramic layer shows evidences of discontinuous or abnormal grain growth.

The wording “discontinuous or abnormal grain growth” is herein used having the technical definition within the specific technical field. Growth phenomena can be separated into continuous growth when microstructure evolves in a uniform manner, and discontinuous growth. In the latter, the changes occur heterogeneously and specific regions with inhomogeneous grain sizes may be identified.

Discontinuous grain growth is characterized by a subset of grains growing at a high rate and at the expense of their neighbours and tends to result in a microstructure dominated by a few very large grains.

Thus, a sign of abnormal grain growth is an inhomogeneity in the characteristic size of the grains present in the densified layer.

In some further embodiments according to the third aspect of the invention the at least one densified porous ceramic layer has a monodisperse porosity in the submicron range, typically preferentially oriented, interconnected or localized at the grain boundary and at the triple point, thereby generated in constrained sintering conditions.

Monodisperse porosity is herein defined as a porosity due to the presence of porous with a size distribution having standard deviations σ<5%, e.g. in diameter. Submicron range is herein defined in the range between 100 nm and 1 μm.

The porous may be oriented in the same direction of the stress forces induced by constrained sintering. The wording “triple point” is herein used having the technical definition within the specific technical field. The triple point is the point where three grains meet within the layer, i.e. a three grains junction.

In some other embodiments according to the third aspect of the invention the at least one layer of said selected system of ceramic layers has a polydisperse porosity. Polydisperse porosity size is herein defined as a porosity due to the presence of porous with a size distribution having standard deviations σ>5%, e.g. in diameter. For example, this may be due to agglomeration phenomena in the staring powders material or defects of deposition.

The multilayer system of the invention may be characterized by a grain size ratio between the at least one densified porous ceramic layer and the at least one layer of said selected system of ceramic layers is in the range between, 0.1 and 10.

In general, by using the method of the invention it appears clear when the top densified porous layer has been introduced on top of a previously deposited layer as the grain size of the top densified layer differs from the one of the layer below previously deposited.

In further embodiments according to the third aspect of the invention the at least one densified porous ceramic layer comprises one or more sintering aids.

In even further embodiments according to the third aspect of the invention the at least one densified porous ceramic layer comprises one or more sintering aids embedded into one or more grains of the at least one densified porous ceramic layer.

In other embodiments according to the third aspect of the invention the one or more sintering aids are present in a concentration between 1 and 30% vol within 1 μm below the top surface of said at least one densified porous ceramic layer.

For example, the one or more sintering aids may be present in a concentration higher than 5% vol within 1 μm below the top surface of said at least one densified porous ceramic layer.

The densified porous ceramic layer may be defined as generally having a top and a bottom surface, wherein the bottom surface is the surface in contact with the selected system of ceramic layers. Thus, the top surface of the densified porous ceramic layer is the emerging surface following the pre-sintering step.

In some embodiments the relative density at the interface between the at least one densified porous ceramic layer and the selected system of ceramic layers is higher than 80% vol.

It has been observed that the bottom interface between the at least one densified porous ceramic layer and the below selected system of ceramic layers densifies better that the top surface of the at least one densified porous ceramic layer.

This is not the case in constrain sintering. Generally constrain sintering generates a residual porosity at the interface between the densified layer and the underneath layer. On the contrary, the method of the invention allows for reduction if not complete elimination of residual porosity at this interface as it is showed by the presence of a continuous between the two layers. The method of the invention therefore has the advantage of increasing the quality of the interface and of reducing the risk of delamination between the densified layer and the underneath layer. Relative density is herein defined as the ration between the effective density and the theoretical density, i.e. a relative density of 80% vol implies 80% of material and 20% of porous.

In a forth aspect of the invention, the object and further objects of the present invention may be achieved through a method for extracting impurities from a densified porous ceramic layer, said method comprising: impregnating a solution or a suspension of one or more sintering aids directly onto a pre-sintered porous ceramic layer; evaporating said solution or suspension to obtain a homogeneous dispersion of the one or more sintering aids in the pre-sintered porous ceramic layer; performing a thermal treatment by applying a temperature T₂ to the pre-sintered porous ceramic layer, where T₂ is higher than the pre-sintering temperature, thereby extracting impurities from the densified porous ceramic layer; and chemical etching the extracted impurities from the densified porous ceramic layer surface.

In some embodiments according to the fourth aspect of the invention the impurities may comprise Si and/or Ca and/or Al.

The first, second and other aspects of the present invention may each be combined with any of the other aspects. These and other aspects of the invention will be apparent from and elucidated with reference to the embodiments described hereinafter.

The invention is described in more detail in the following examples.

### EXAMPLES

The examples describe the theoretical considerations and the practical experiments, which have led to the present invention. The starting point has been a desire to densify and tighten the porous barrier layers, which are inserted between the electrolyte and an electrode in solid oxide cells. This has been done partly by changing the conventional sintering process and partly by selecting specific sintering aids and sintering temperatures and times.

The sintering aids are selected among a number of metal salts and/or oxides and other materials which present a high diffusivity in the relevant temperature range. The sintering aid should also be fully compatible with the system. At present, the most preferred sintering aid is cobalt oxide originating from cobalt nitrate or being provided as a powder. The choice of cobalt oxide as the most preferred sintering aid is due to the fact that cobalt oxide has a high diffusion coefficient and moreover a limited solubility in CeO₂. The diffusion coefficient D_{Co} in CoO is approximately 10⁻⁸ cm²/sec at 1200° C., whereas e.g. D_{Zr} in Ca-doped Zr is approximately 10⁻¹⁴ cm²/sec at 1200° C.

### Example 1

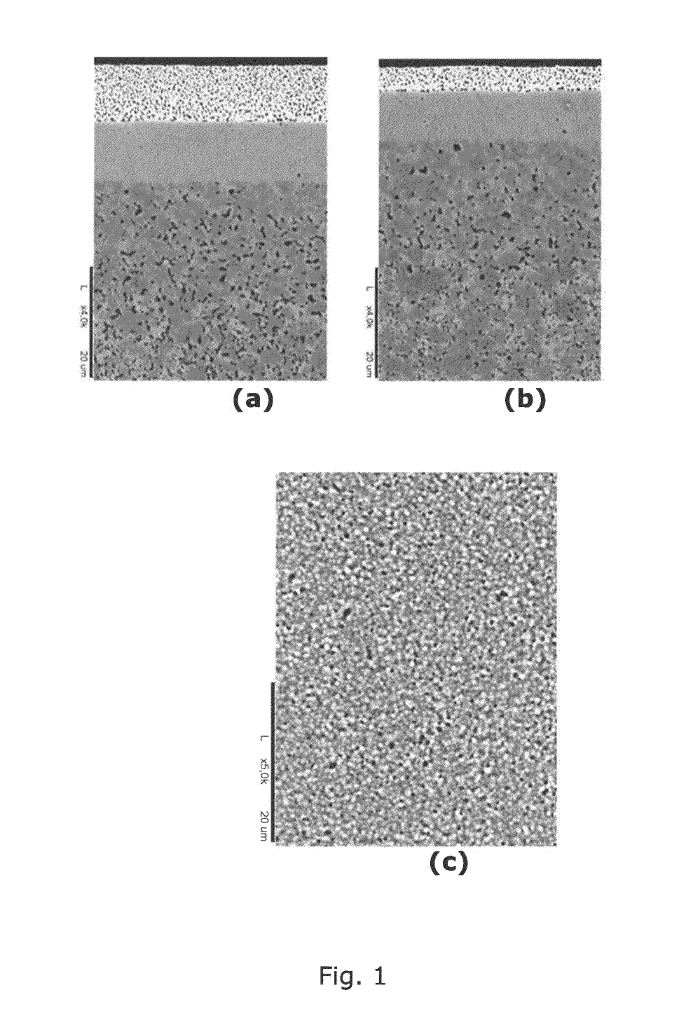

This example deals with the conventional way of sintering, where the sintering aid, if any, is added to the starting powders before sintering. FIG. 1 shows the porosity appearance of a tape cast barrier layer (multi tape casting) in two cases: (a) sintering for 12 hours at 1250° C., calcined CGO, no sintering aid present, and (b) sintering for 12 hours at 1250° C., calcined CGO, sintering aid 2 mole % Co₃O₄ added in the starting powders. The appearance of the barrier layer viewed from the top is shown in FIG. 1(c); the surface of the barrier layer is clearly porous.

### Example 2

Densifying and tightening the barrier layer successfully is mainly a question of optimizing temperature and treatment times. However, a number of conditions, some of which may be mutually conflicting, have to be taken into consideration.

Sintering at the desired or necessary high temperatures is a possible source of tensile stress in the barrier layer and shrinkage of the support, resulting in tensions in the multilayer system. At the same time, sintering stresses affect the grain growth, which in turn is critical to obtain a densified surface.

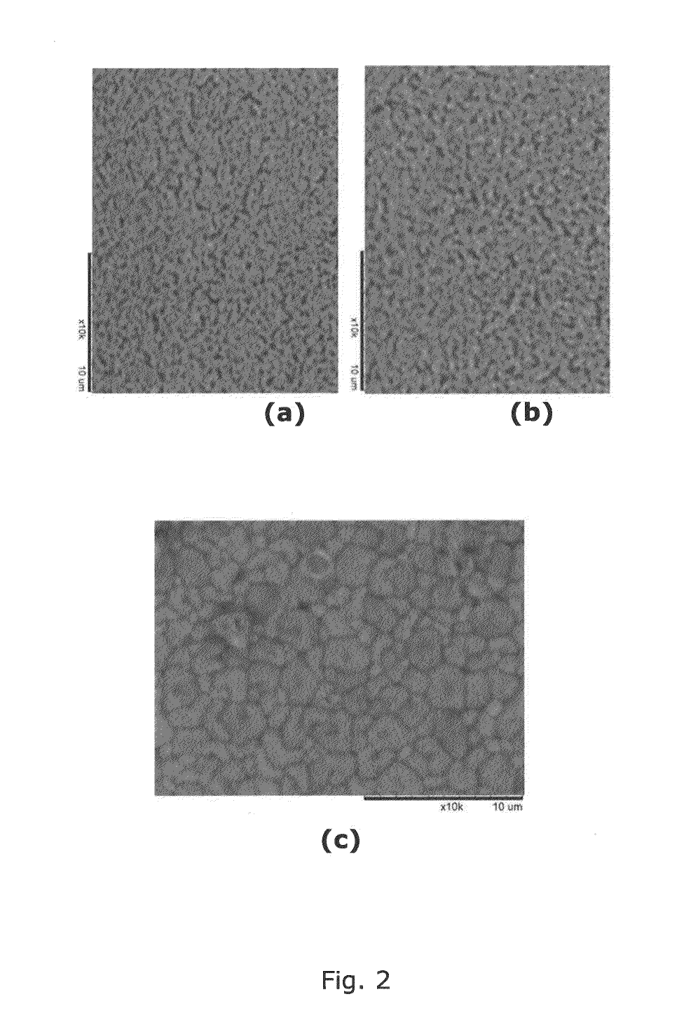

A solid oxide half cell was assembled by lamination of support, anode and electrolyte green layers and then sintered. Then it was coated with a barrier layer of doped ceria starting powders enriched with 2 mole % Co₃O₄ and deposited by screen printing. The half cell with the barrier layer was then pre-sintered at 1250° C. for 2 hours, displaying the surface structure shown in FIG. 2(a). Further sintering at 1275° C. for 3 hours gave the structure shown in FIG. 2(b). It is clearly seen that virtually no grain growth has taken place.

The FIGS. 2(a), 2(b) and 2(c) show a direct comparison between the microstructures obtained for screen printed barrier layers by identical thermal treatment but different chemical routes. More specifically, a barrier layer consisting of CGO with the sintering aid added with the starting powders and sintered at 1250° C. for 2 hours (FIG. 2(a)) shows enhanced growth and densification, when it is further impregnated with cobalt nitrate solution and sintered again at 1275° C. for 3 hours under solid state reaction conditions (FIG. 2(c)), over the one simply sintered at 1275° C. for 3 hours with no impregnation (FIG. 2(b)).

### Example 3

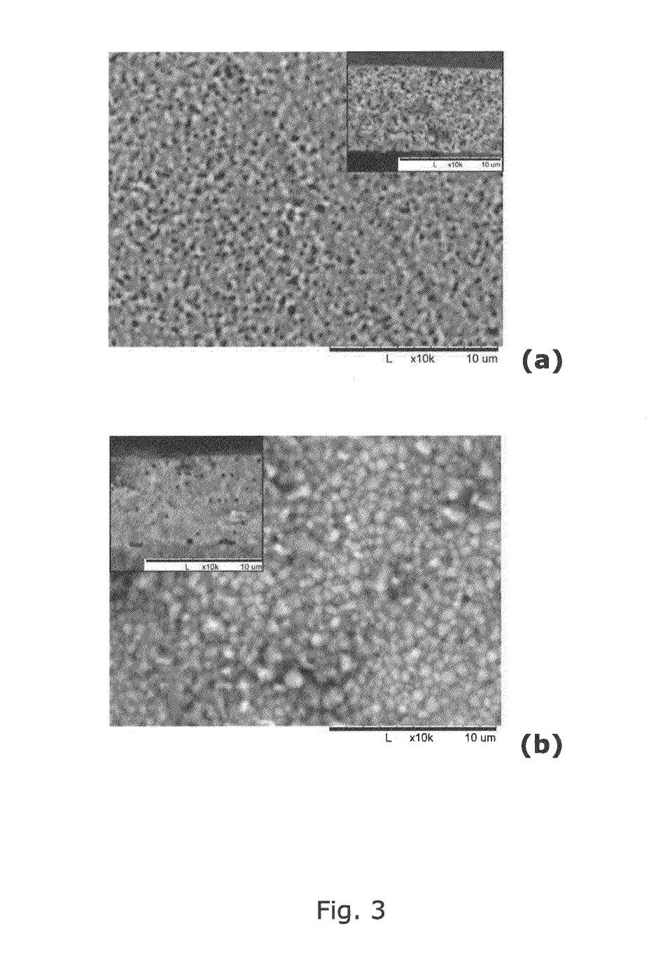

This example shows that the method according to the invention makes it possible to reduce the maximum temperature used in the processing. A multi casted half-cell consisting of a support, an anode, an electrolyte and a dense barrier layer is sintered according to the method of the invention, first at 1200° C. for 5 hours. Then cobalt nitrate is applied by impregnation, and the assembly is sintered again, this time at 1250° C. for 3 hours. FIG. 3(a) shows the structure after the first sintering, where no sintering aid was used in the CGO starting powders, and FIG. 3(b) shows the resulting structure after impregnation and a second sintering. A nearly dense barrier layer with markedly enlarged grains is obtained.

The following numbered items provide in term of conceptual statements further disclosure of the present subject matter.

1. A method for the densification of ceramic layers by an in-situ solid state reaction, said method comprising the following steps:
(a) providing a multilayer system by depositing the porous ceramic layer, which is to be densified, onto the selected system of ceramic layers on a support,
(b) pre-sintering the resulting multilayer system at a temperature T₁ to consolidate a sintered, but porous layer,
(c) impregnating a solution or suspension of one or more sintering aids directly into the layer to be densified,
(d) evaporating the solution or suspension of step (c) to obtain a homogeneous dispersion of the sintering aid(s) in the porous layer surface and
(e) performing a thermal treatment at a temperature T₂, where T₂>T₁, to obtain densification of and grain growth in the porous layer formed in step (b).
   2. Method according to item 1, wherein the porous ceramic layer to be densified consists of gadolinium-doped cerium oxide (CGO).
   3. Method according to item 2, wherein T₁ is in the 850-1350° C. range and T₂>T₁.
   4. Method according to any of the items 1-3, wherein the sintering aid is selected from the group consisting of Co, Fe, Cr, Mn, Ni, Zn, Cu, Bi, Li, K, Ca or Ba salts and/or oxides and their mixtures, which present a high diffusivity in the temperature range about 600-1400° C. and electrical conductivity/catalytic properties under the operative conditions of SOFCs.
   5. Method according to any of the preceding items, wherein the deposition in step (a) is done by casting, multi casting and lamination at the green stage, by screen printing, by spraying techniques, by physical vapour deposition (PVD) or by chemical vapour deposition (CVD).
   6. Method according to item 4, wherein the sintering aid is selected from cobalt oxides and cobalt salts.
   7. A multilayer system with a densified ceramic layer, especially for use within solid oxide cell (SOC) technology, which is produced by a method according to any of the preceding items.
   8. A method for the densification of porous ceramic layers by an in-situ solid state reaction, said method comprising:
(a) providing a multilayer system by depositing the porous ceramic layer, which is to be densified, onto the selected system of ceramic layers on a support,
(b) pre-sintering the resulting multilayer system by applying a temperature T₁ to said multilayer system thereby consolidating and pre-sintering, said porous ceramic layer,
(c) impregnating a solution or suspension of one or more sintering aids directly into said porous ceramic layer to be densified,
(d) evaporating the solution or suspension of step (c) to obtain a homogeneous dispersion of the sintering aid(s) in said porous ceramic layer and
(e) performing a thermal treatment by applying a temperature T₂ to said multilayer system, where T₂>T₁, thereby obtaining densification of and grain growth in said porous layer formed in step (b).

1. A method for the densification of porous ceramic layers by an in-situ solid state reaction, said method comprising:
(a) providing a multilayer system by depositing the porous ceramic layer, which is to be densified, onto the selected system of ceramic layers on a support,
(b) pre-sintering the resulting multilayer system by applying a temperature T1 to said multilayer system thereby consolidating and pre-sintering, said porous ceramic layer,
(c) impregnating a solution or suspension of one or more sintering aids directly into said porous ceramic layer to be densified,
(d) evaporating the solution or suspension of step (c) to obtain a homogeneous dispersion of the sintering aid(s) in said porous ceramic layer and
(e) performing a thermal treatment by applying a temperature T2 to said multilayer system, where T2>T1, thereby obtaining densification of and grain growth in said porous layer formed in step (b) and thus providing a densified porous ceramic layer having a structure where a grain size (g) and thickness (t) of the densified porous ceramic layer stand in relation to one another as given by
g/t>0.1.

2. Method according to claim 1, wherein the porous ceramic layer to be densified consists of gadolinium-doped cerium oxide (CGO).

3. Method according to claim 2, wherein T1 is in the 850-1350° C. range and T2>T1.

4. Method according to claim 1, wherein said one or more sintering aids are selected from the group consisting of Co, Fe, Cr, Mn, Ni, Zn, Cu, Bi, Li, K, Ca or Ba salts and/or oxides and their mixtures.

5. Method according to claim 1, wherein the deposition in step (a) is done by casting, multi casting and lamination at the green stage, by screen printing, by spraying techniques, by physical vapour deposition (PVD) or by chemical vapour deposition (CVD).

6. Method according to claim 4, wherein said one or more sintering aids are selected from cobalt oxides and cobalt salts.

7. A method according to claim 1, said method further comprising:
(f) a selected chemical etching to remove traces of said one or more sintering aids thereby cleaning said densified porous ceramic layer.

8. Use of a multilayer system with a densified ceramic layer produced by a method according to claim 1, within solid oxide cell (SOC) technology.

9. Use of a multilayer system with a densified ceramic layer produced by a method according to claim 1, within piezo-electric technology.

10. A multilayer system, comprising:
a selected system of ceramic layers on a support
at least one densified porous ceramic layer, located on top of said selected system of ceramic layers,
wherein said at least one densified porous ceramic layer has a structure where a grain size (g) and thickness (t) of said at least one densified porous ceramic layer stand in relation to one another as given by
g/t>0.1.

11. A multilayer system, according to claim 10, wherein said at least one densified porous ceramic layer shows evidences of discontinuous or abnormal grain growth.

12. A multilayer system, according to claim 10, wherein said at least one densified porous ceramic layer has a monodisperse porosity in the submicron range, oriented in the same direction of the stress forces induced by constrained sintering, interconnected or localized at the grain boundary and at the triple point, thereby generated in constrained sintering conditions.

13. A multilayer system, according to claim 10, wherein said at least one layer of said selected system of ceramic layers has polydisperse porosity.

14. A multilayer system, according to claim 10, wherein said at least one densified porous ceramic layer comprises one or more sintering aids.

15. A multilayer system, according to claim 14, wherein said at least one densified porous ceramic layer comprises one or more sintering aids embedded into one or more grains of said at least one densified porous ceramic layer.

16. A multilayer system, according to claim 14, wherein said one or more sintering aids are present in a concentration between 1 and 30% vol within 1 μm below the top surface of said at least one densified porous ceramic layer.

17. A multilayer system, according to claim 14, wherein said one or more sintering aids are present in a concentration higher than 5% vol within 1 μm below the top surface of said at least one densified porous ceramic layer.

18. A multilayer system, according to claim 10, wherein the relative density at the interface between said at least one densified porous ceramic layer and said selected system of ceramic layers is higher than 80% vol.
